(19) United States
(12) Patent Application Publication
(10) Pub. No.: US 2022/0095494 A1
(43) Pub. Date: Mar. 24, 2022

(54) DISPLAY SYSTEM WITH FAN CONTROL AND METHOD THEREOF

(71) Applicant: DYNASCAN TECHNOLOGY CORP., Taoyuan City (TW)

(72) Inventors: Tsun-I WANG, Taoyuan City (TW); Ching-Chun Wu, Taoyuan City (TW); Chia-Liang Yang, Taoyuan City (TW)

(21) Appl. No.: 17/027,446

(22) Filed: Sep. 21, 2020

(51) Int. Cl. H05K 7/20

(52) U.S. Cl. CPC H05K 7/20972; H05K 7/20209

(57) ABSTRACT

A display system with fan control which includes a display module, a fan, a temperature detector and a fan controller is provided. The fan is configured to generate an air flow in the display system. The temperature detector is configured to detect temperature within the display system. The fan controller is configured to generate a control signal to control a rotational speed of the fan based on the detected temperature and a first time period since the detected temperature reaches a first threshold and in which the detected temperature remains equal to or higher than the first threshold. The fan controller remains the rotational speed of the fan unchanged when the detected temperature is lower than the first threshold.

### BACKGROUND

### 1. Field of the Disclosure

The present invention relates to a display system with fan control and a method thereof, and more specifically, to a display system with fan control capable of modulating a rotational speed associated with temperature.

### 2. Description of Related Art

As increased efficiency is required for display systems, problems relating to heat dissipation may arise. If heat generated by the inner components of electronic products cannot be dissipated efficiently, the stability and efficiency of display system operations will be affected. This may even result in mechanical malfunction, thereby causing damage to the display system. Therefore, a display system with fan control is needed to decrease temperature efficiently and to improve reliability.

### SUMMARY

According to some example embodiments of the instant disclosure, a display system with fan control includes a display module, a fan, a temperature detector and a fan controller. The fan is configured to generate an air flow in the display system. The temperature detector is configured to detect temperature within the display system. The fan controller is configured to generate a control signal to control a rotational speed of the fan based on the detected temperature and a first time period when the detected temperature reaches a first threshold, and in which the detected temperature remains equal to or higher than the first threshold. The fan controller keeps the rotational speed of the fan unchanged when the detected temperature is lower than the first threshold.

According to some example embodiments of the instant disclosure, a method for fan controlling in display system includes: detecting temperature within the display system; and generating a control signal to control a rotational speed of the fan based on the detected temperature and a first time period when the detected temperature reaches a first threshold and in which the detected temperature remains equal to or higher than the first threshold. The rotational speed of the fan is kept unchanged when the detected temperature is lower than the first threshold.

### BRIEF DESCRIPTION OF THE DRAWINGS

Aspects of the present disclosure are readily understood from the following detailed description when read with the accompanying figures. It should be noted that various features may not be drawn to scale. In fact, the dimensions of the various features may be arbitrarily increased or reduced for clarity of discussion.

FIG. 1 is a functional block diagram illustrating the display system in accordance with some embodiments of the present disclosure.

FIG. 2 is a schematic diagram showing a relationship between the rotational speed and the temperature in accordance with some embodiments of the present disclosure.

FIG. 3A and FIG. 3B are schematic diagrams showing different relationship between the rotational speed and time in accordance with some embodiments of the present disclosure.

FIG. 4 is a schematic diagram showing a relationship between the rotational speed, the temperature and the time in accordance with some embodiments of the present disclosure.

FIG. 5 illustrates a method for fan controlling in a display system in accordance with some embodiments of the present disclosure.

FIG. 6 is a schematic diagram illustrating the display system in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

The following disclosure provides many different embodiments, or examples, for implementing different features of the provided subject matter. Specific examples of components and arrangements are described below. These are, of course, merely examples and are not intended to be limiting. In the present disclosure, reference to the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments of the present disclosure are discussed in detail below. It should be appreciated, however, that the present disclosure provides many applicable concepts that can be embodied in a wide variety of specific contexts. The specific embodiments discussed are merely illustrative and do not limit the scope of the disclosure.

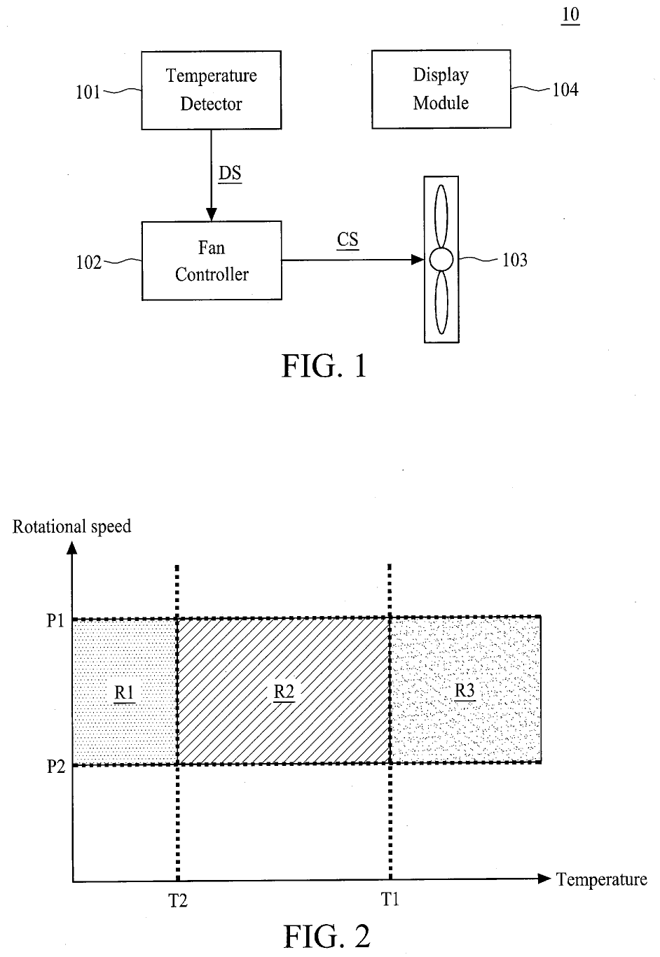

FIG. 1 is a functional block diagram illustrating the display system 10 in accordance with some embodiments of the present disclosure. The display system 10 includes a temperature detector 101, a fan controller 102, a fan 103 and a display module 104. Moreover, the display system 10 may be located outdoor or indoor to display images or video to inform customers and passengers of product and service offerings.

The temperature detector 101 is used to detect temperature within the display system 10 and generate a detecting signal DS indicating the detected temperature within the display system 10. The detecting signal DS can be any form of signal, such as a pulse width modulation (PWM) signal, a voltage-controlled signal or a current-controlled signal.

The fan controller 102 receives the detecting signal DS and generates a control signal CS to control a rotational speed of the fan 103. The control signal CS is determined by the fan controller 102 according to the detecting signal DS. The fan controller 102 could include a digital signal processor (DSP), a microcontroller (MCU), a central-processing unit (CPU) or a plurality of parallel processors relating the parallel processing environment to implement the operating system (OS), firmware, driver and/or other applications of the display system 10. In some embodiments, the fan controller 102 may be implemented with a single transistor to control the on/off status of the fan 103.

The fan 103 is used to generate an air flow toward, passing by, or surrounding the display module 104 in the display system 10 so as to reduce the temperature of the display system 10. The control signal CS is transmitted from the fan controller 102 to the fan 103 to modulate the rotational speed of the fan 103. The rotational speed of the fan 103 is determined based on the control signal CS of the fan controller 102. The control signal CS can be any form of signal, such as a pulse width modulation (PWM) signal, a voltage-controlled signal or a current-controlled signal.

The display module 104 is used to display various kinds of information, such as goods and services for sale. The display module 104 could be a projective display device, a 3D-image display device, an organic LED display, an electronic paper, a system-integrated panel, an LED display liquid-crystal panel, or a touch display panel such as a resistive touch panel, capacitive touch panel, optical touch panel or electromagnetic touch panel.

FIG. 2 is a schematic diagram showing a relationship between the rotational speed of the fan 103 and the detected temperature within the display system 10 in accordance with some embodiments of the present disclosure. Three regions R1 to R3 are defined by two thresholds T1, T2 and two rotational speeds P1, P2. The rotational speed P1 is the maximum rotational speed of the fan 103, and the rotational speed P2 is the minimum rotational speed of the fan 103. Accordingly, the rotational speed of the fan 103 is predetermined within the range between the rotational speeds P1 and P2, and the speed can be adjusted with reference to the thresholds T1 and T2 of the detected temperature.

As shown in FIG. 2, the threshold T1 is greater than the threshold T2, and the rotational speed P1 is greater than the rotational speed P2. The regions R1 to R3 are arranged between the rotational speeds P1 and P2. The threshold T1 defines the boundary of the regions R2 and R3, and the threshold T2 defines the boundary of the regions R1 and R2. More specifically, the rotational speed is decreased in the region R1 but not less than the rotational speed P2; the rotational speed remains unchanged in the region R2, and the rotational speed is increased in the region R3 but not greater than the rotational speed P1.

When the detected temperature of the display system 10 is equal to or higher than the threshold T1, the rotational speed enters the region R3 and is increased until it reaches the rotational speed P1. Meanwhile, the fan controller 102 monitors the first time period in which the detected temperature is equal to or higher than the threshold T1. The fan controller 102 may be configured to increase the rotational speed of the fan 103 continuously as the first time period increases. The fan controller 102 may be configured to increase the rotational speed of the fan 103 gradually as the first time period increases. The fan controller 102 may be configured to increase the rotational speed of the fan 103 sequentially as the first time period increases. More specifically, the rotational speed is increased continuously as the first time period increases until the rotational speed reaches the rotational speed P1.

Afterwards, when the detected temperature decreases and is smaller than the threshold T1, the rotational speed may remain unchanged, but enters the region R2 from the region R3. The rotational speed may remain unchanged when the temperature is between T1 and T2. The increase of the rotational speed may stop as the first time period ends.

When the detected temperature of the display system 10 is equal to or less than the threshold T2, the rotational speed enters the region R1 and is decreased until it reaches the rotational speed P2. Meanwhile, the fan controller 102 monitors the second time period in which the detected temperature is equal to or less than the threshold T2. The fan controller 102 may be configured to decrease the rotational speed of the fan 103 continuously as the second time period increases. The fan controller 102 may be configured to decrease the rotational speed of the fan 103 gradually as the second time period increases. The fan controller 102 may be configured to decrease the rotational speed of the fan 103 sequentially as the second time period increases. More specifically, the rotational speed is decreased continuously as the second time period increases until the rotational speed reaches the rotational speed P2.

Afterwards, when the detected temperature increases and is greater than the threshold T2, the rotational speed may remain unchanged but enters the region R2 from the region R1. The decrease of the rotational speed may stop as the second time period ends. The rotational speed may remain unchanged when the temperature is between T1 and T2.

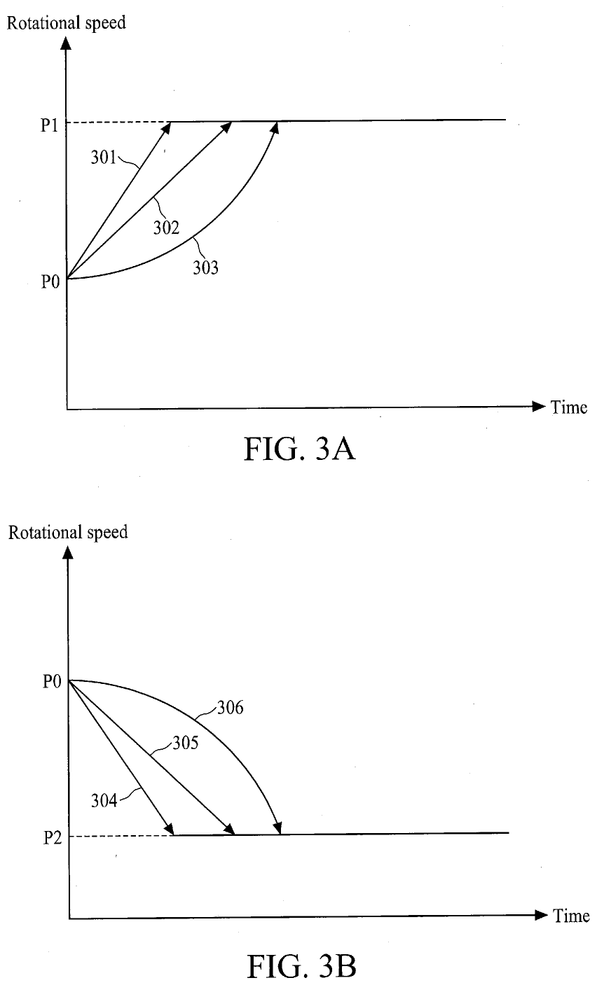

FIG. 3A depicts curves illustrating different rates of increase of the rotational speed in accordance with some embodiments of the present disclosure. The increasing rate of the rotational speed is proportional to the length of the first time period. The rotational speed of the fan 103 can be increased from the rotational speed P0 to the rotational speed P1 by three increasing rates 301-303. The increasing rate 301 is greater than the increasing rate 302, and increasing rate 303 is not a constant. The increasing rate 303 may be proportional to the length of the first time period.

Referring to FIG. 2 and FIG. 3A The first time period indicates the period where the detected temperature of the display system 10 is equal to or greater than the threshold T1. It is contemplated that the longer the first time period is, the more the detected temperature needs to be decreased. The high temperature may cause heat to accumulate in the display apparatus which causes irreversible damage to the display, such as liquefaction or yellowing of the liquid crystal layer. Thus, according to the present disclosure, the rotational speed of the fan increases as the first time period increases. As the first time period increases, the increasing rate of the rotational speed can be adjusted correspondingly by the fan controller 102 according to any one of the increasing rates 301-303. The increasing rate may be chosen based in the setting or operation mode of the display apparatus or the environment outside of the display apparatus. Therefore, the temperature of the display system 10 could be adaptively and efficiently adjusted to prevent the display system 10 from being damaged due to abnormal temperature.

More specifically, the curves of the increasing rates of the rotational speed further integrate the system noise and heat transfer, and complies with the user's specification so as to generate the optimal operation curve of the rotational speed of the fan 103. For example, if the user prefers avoiding the noise of the display system 10, a low increasing rate, such as the increasing rate 302, can be selected by the fan controller 102 for generating the control signal CS. If the user puts a high priority on heat dissipation, a high increasing rate, such as the increasing rate 301, or increasing rate 303, could be selected by the fan controller 102 to improve the sensitivity of the rotational speed toward the detected temperature and to dissipate heat effectively.

FIG. 3B depicts curves illustrating different decreasing rates of the rotational speed in accordance with some embodiments of the present disclosure. The decreasing rate of the rotational speed is proportional to the length of the second time period. The rotational speed of the fan 103 could be decreased from the rotational speed P0 to the rotational speed P2 by three decreasing rates 304-306. The decreasing rate 304 is greater than the decreasing rate 305, and the decreasing rate 305 is not a constant. The decreasing rate 305 may be proportional to the length of the second time period

The second time period indicates the period where the detected temperature of the display system 10 is equal to or less than the threshold T2. The longer the second time period is, the more the detected temperature needs to be increased. As the second time period increases, the decreasing rate of the rotational speed could be modulated correspondingly by the fan controller 102 from the increasing rate 306 to the increasing rate 305 even the increasing rate 304. The decreasing rate may be chosen based on the setting or operation mode of the display apparatus or the environment outside of the display apparatus.

Therefore, the temperature of the display system 10 could be adaptively and efficiently adjusted to prevent the display system 10 from being damaged due to abnormal temperatures. In addition, the adjustments on the rotational speed associated with the detected temperature executed by the fan controller 102 can provide and increase the flexible operation for the display system 10 without needing additional or more complicated circuit elements.

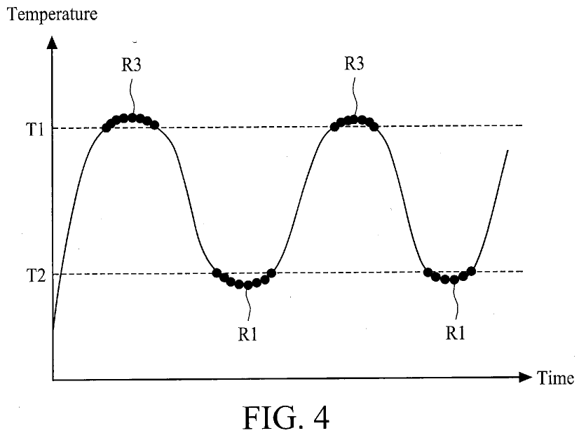

FIG. 4 is a schematic diagram showing a relationship between the rotational speed, the temperature and time in accordance with some embodiments of the present disclosure. Generally, the normal temperature of the display system 10 is between the two thresholds T1 and T2. Referring to FIG. 2 and FIG. 4, when the detected temperature exceeds the threshold T1, the rotational speed enters the region R3 and the rotational speed is increased. Furthermore, the increasing rate can be modulated corresponding to the first time period so as to swiftly pull down the detected temperature to be less than the threshold T1.

After the detected temperature is smaller than the threshold T1, the rotational speed remains unchanged unless it reaches the threshold T2. When the detected temperature is below the threshold T2, the rotational speed enters the region R1 and the fan controller 102 starts decreasing the rotational speed. Furthermore, the decreasing rate could be modulated corresponding to the second time period so as to pull up the detected temperature to be greater than the threshold T2. Therefore, the display system 10 can be kept within the normal temperature between the thresholds T1 and T2 to maintain its system stability and display performance.

More specifically, the thresholds T1 and T2 are configured based on environmental temperature of the display system 10. When the display system 10 is located outdoors or in a tropical area, the high thresholds T1 and T2 can be predetermined by the fan controller 102 in correspondence with high environmental temperatures. Similarly, low thresholds T1 and T2 could also be predetermined when the environmental temperature of the display system 10 is low.

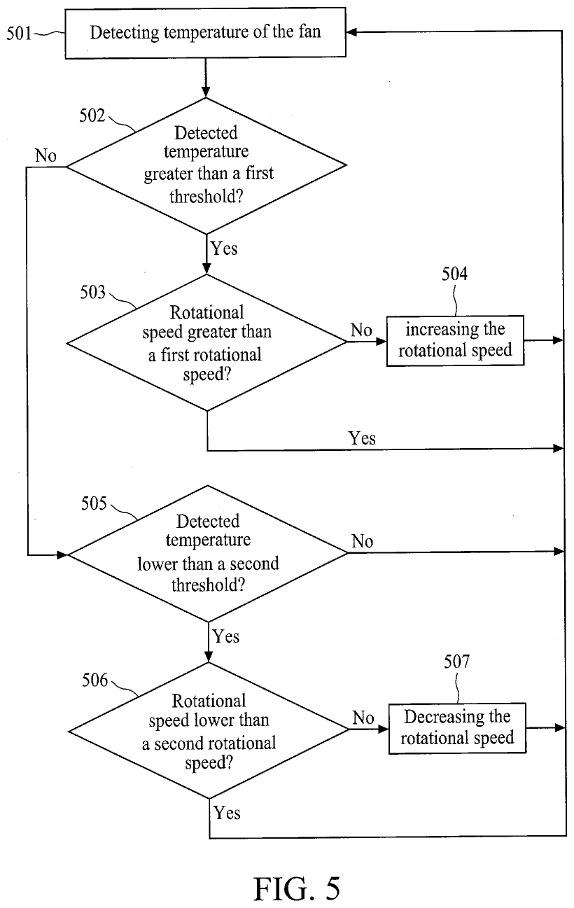

FIG. 5 illustrates a method for fan controlling in display system 10 in accordance with some embodiments of the present disclosure. The method can be applied for the display unit 10 of FIG. 1, but is not limited thereto. In step 501, temperature of the fan is detected. In step 502, whether the detected temperature is greater than a first threshold or not is determined.

If the detected temperature is greater than the first threshold, step 503 will be executed. If not, step S505 will be executed. In step S503, whether or not the rotational speed is greater than a first rotational speed is determined. If so, the method goes back to step S501; if not, step 504 will be executed so that the rotational speed is increased.

In step S505, whether the detected temperature is lower than a second threshold or not is determined. If so, step S506 will be executed; if not, the method goes back to step S501. In step S506, whether or not the rotational speed is lower than a second rotational speed is determined. If so, the method goes back to step S501; if not, step 507 will be executed so that the rotational speed is decreased.

Please refer to FIG. 1 again. In some embodiments, the temperature detector 101 may include a temperature sensing chip. In this case, the detecting signal DS can be a PWM signal. The rotational speed of the fan 103 is proportional to the duty cycle of the PWM signal. In some embodiments, the temperature detector 101 includes at least one thermistor or other kinds of temperature-sensitive resistors, which may reduce the cost of temperature detector 101. In this case, the detecting signal DS can be a voltage-controlled signal or a current-controlled signal.

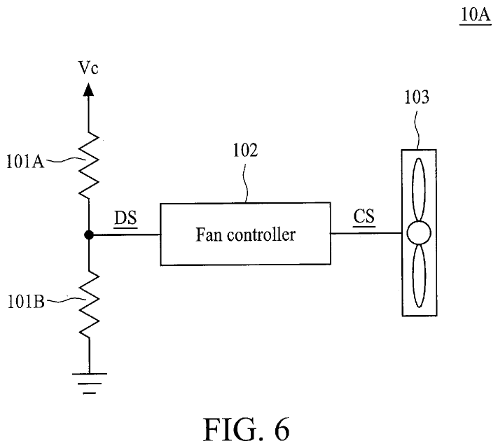

FIG. 6 is a schematic diagram illustrating the display system 10A in accordance with some embodiments of the present disclosure. The display system 10A is similar to the display system 10 of FIG. 1 except that two resistors 101A and 101B are arranged as a temperature detector. The voltage source Vc is provided for powering the display system 10A, and the resistors 101A and 101B are connected in series between the voltage source Vc and the ground.

Specifically, one of the resistors 101A and 101B is a thermistor while the other one is a resistor whose resistance remains substantially the same as its temperature varies. By applying the above arrangement of the thermistor, the divided voltage at the node between the resistors 101A and 101B varies based on the temperature of the display system 10A, and the detecting signal DS can be used to indicate the detected temperature. Accordingly, the detecting signal DS can be transmitted to the fan controller 102 for modulating the rotational speed of the fan 103.

By utilizing the thermistor, the temperature of the display system 10C can be easily detected for controlling the rotational speed of the fan 103 without requiring additional circuit elements. Therefore, the size and manufacturing cost of the display system 10C can be reduced.

Spatially relative terms, such as “beneath,” “below,” “lower,” “above,” “upper,” “lower,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

The terms “approximately,” “substantially,” “substantial” and “about” are used herein to describe and account for small variations. When used in conjunction with an event or circumstance, the terms can refer to instances in which the event or circumstance occurs precisely, as well as instances in which the event or circumstance occurs to a close approximation. As used herein with respect to a given value or range, the term “about” generally means within ±10%, ±5%, ±1%, or ±0.5% of the given value or range. Ranges can be expressed herein as being from one endpoint to another endpoint or between two endpoints. All ranges disclosed herein are inclusive of the endpoints, unless specified otherwise. The term “substantially coplanar” can refer to two surfaces within micrometers (μm) of lying along a same plane, such as within 10 μm, within 5 μm, within 1 μm, or within 0.5 μm of lying along the same plane. When referring to numerical values or characteristics as “substantially” the same, the term can refer to the values lying within ±10%, ±5%, ±1%, or ±0.5% of an average of the values.

The foregoing outlines the features of several embodiments and detailed aspects of the present disclosure. The embodiments described in the present disclosure may be readily used as a basis for designing or modifying other processes and structures for carrying out the same or similar purposes and/or achieving the same or similar advantages of the embodiments introduced herein. Such equivalent constructions do not depart from the spirit and scope of the present disclosure, and various changes, substitutions, and alterations may be made without departing from the spirit and scope of the present disclosure.

1. A display system with fan control, comprising:
a display module;
a fan configured to generate an air flow in the display system;
a temperature detector, configured to detect temperature within the display system; and
a fan controller, configured to generate a control signal to control a rotational speed of the fan based on the detected temperature and a first time period since the detected temperature reaches a first threshold, in which the detected temperature remains equal to or higher than the first threshold, wherein the fan controller remains the rotational speed of the fan unchanged when the detected temperature is lower than the first threshold.

2. The display system as claimed in claim 1, wherein the fan controller is configured to increase the rotational speed of the fan sequentially as the first time period increases.

3. The display system as claimed in claim 2, wherein the fan controller is configured to increase the rotational speed of the fan continuously as the first time period increases until the rotational speed reaches a first rotational speed.

4. The display system as claimed in claim 3, wherein an increasing rate of the rotational speed is proportional to the length of the first time period.

5. The display system as claimed in claim 1, wherein the fan controller is configured to control the rotational speed of the fan based on the detected temperature and a second time period since the detected temperature reaches a second threshold, and in which the detected temperature remains equal to or lower than the second threshold.

6. The display system as claimed in claim 5, wherein the fan controller remains the rotational speed of the fan unchanged when the detected temperature is between the first threshold and the second threshold, and wherein the second threshold is lower than the first threshold.

7. The display system as claimed in claim 5, wherein the fan controller is configured to decrease the rotational speed of the fan sequentially as the second time period increases until the rotational speed reaches a second rotational speed.

8. The display system as claimed in claim 5, wherein a decreasing rate of the rotational speed is proportional to the length of the second time period.

9. The display system as claimed in claim 1, wherein the control signal is a pulse width modulation (PWM) signal, a voltage-controlled signal or a current-controlled signal.

10. The display system as claimed in claim 1, wherein the temperature detector comprises a thermistor.

11. The display system as claimed in claim 1, wherein the first threshold and the second threshold are configured based on environmental temperatures of the display system.

12. A method for fan controlling in display system, comprising:
detecting temperature within the display system; and
generating a control signal to control a rotational speed of the fan based on the detected temperature and a first time period since the detected temperature reaches a first threshold, and in which the detected temperature remains equal to or higher than the first threshold, wherein the rotational speed of the fan is remained unchanged when the detected temperature is lower than the first threshold.

13. The method as claimed in claim 12, further comprising: increasing the rotational speed of the fan sequentially as the first time period increases.

14. The method as claimed in claim 13, further comprising: increasing the rotational speed of the fan continuously as the first time period increases until the rotational speed reaches a first rotational speed.

15. The method as claimed in claim 14, wherein an increasing rate of the rotational speed is proportional to the length of the first time period.

16. The method as claimed in claim 12, further comprising: controlling the rotational speed of the fan based on the detected temperature and a second time period since the detected temperature reaches a second threshold, and in which the detected temperature remains equal to or lower than the second threshold.

17. The method as claimed in claim 16, further comprising: remaining the rotational speed of the fan unchanged when the detected temperature is between the first threshold and the second threshold, and wherein the second threshold is lower than the first threshold.

18. The method as claimed in claim 16, further comprising: decreasing the rotational speed of the fan sequentially as the second time period increases until the rotational speed reaches a second rotational speed.

19. The method as claimed in claim 16, wherein a decreasing rate of the rotational speed is proportional to the length of the second time period.

20. The method as claimed in claim 12, wherein the first threshold and the second threshold are configured based on environmental temperature of the display system.
